(19) United States
(12) Patent Application Publication
(10) Pub. No.: US 2026/0240035 A1
(43) Pub. Date: Aug. 13, 2026

(54) SEMICONDUCTOR DEVICE

(71) Applicant: SHINKO ELECTRIC INDUSTRIES CO., LTD., Nagano (JP)

(72) Inventor: Kenichi KOI, Nagano (JP)

(21) Appl. No.: 19/538,129

(22) Filed: Feb. 12, 2026

(30) Foreign Application Priority Data
Feb. 13, 2025 (JP) 2025-021437

(51) Int. Cl. H10W 74/10; H10W 72/90

(52) U.S. Cl. CPC H10W 74/117; H10W 72/9413; H10W 72/9415; H10W 74/142

(57) ABSTRACT

A semiconductor device includes an insulating substrate, a semiconductor element bonded to a first surface of the insulating substrate through a bonding layer with first and second electrodes of the semiconductor element facing toward the insulating substrate, a first and a second interconnect formed on a second surface of the insulating substrate and electrically connected to the first and second electrodes via a first and a second via interconnect each piercing through the insulating substrate and the bonding layer, respectively, an insulating layer positioned between the first and second interconnects on the second surface of the insulating substrate, a first wiring member over the first and second interconnects, a second wiring member below the semiconductor element, and an encapsulation resin covering the semiconductor element and the first and second interconnects. Part of the first interconnect and part of the second interconnect protrude from the encapsulation resin in a plan view.

### CROSS-REFERENCE TO RELATED APPLICATION

This application is based upon and claims the benefit of priority of Japanese Patent Application No. 2025-021437, filed on Feb. 13, 2025, the entire contents of which are incorporated herein by reference.

### FIELD

A certain aspect of the embodiment discussed herein is related to semiconductor devices.

### BACKGROUND

A semiconductor device including a semiconductor device and heat sinks provided one on each of the top side and the bottom side of the semiconductor device, which are encapsulated by an encapsulation resin, has been known. This semiconductor device has an electrode connected to a terminal via a bonding wire in the encapsulation resin, from which part of the terminal projects. (See, for example, Japanese Laid-open Patent Publication No. 2016-100479.)

### SUMMARY

According to an aspect, a semiconductor device includes an insulating substrate, a semiconductor element bonded to a first surface of the insulating substrate through a bonding layer with first and second electrodes of the semiconductor element facing toward the insulating substrate, a first and a second interconnect formed on a second surface of the insulating substrate and electrically connected to the first and second electrodes via a first and a second via interconnect each piercing through the insulating substrate and the bonding layer, respectively, an insulating layer positioned between the first and second interconnects on the second surface of the insulating substrate, a first wiring member over the first and second interconnects, a second wiring member below the semiconductor element, and an encapsulation resin covering the semiconductor element and the first and second interconnects. Part of the first interconnect and part of the second interconnect protrude from the encapsulation resin in a plan view.

The object and advantages of the invention will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF DRAWINGS

FIG. 1 is a plan view of a semiconductor device according to an embodiment;

FIGS. 2A and 2B are sectional views of the semiconductor device according to the embodiment; and

FIGS. 3A through 3J are diagrams illustrating a process of manufacturing a semiconductor device according to the embodiment.

### DESCRIPTION OF EMBODIMENTS

It is difficult to reduce the thickness of the above-described semiconductor device because a spacer is interposed between the semiconductor device and the top-side heat sink in order to ensure space for placing the bonding wire.

According to an embodiment, it is possible to reduce the thickness of semiconductor devices.

One or more embodiments of the present invention are described below with reference to the accompanying drawings. In the following, elements or components having substantially the same functional configuration are referred to using the same reference numeral, and duplicate description thereof may be omitted.

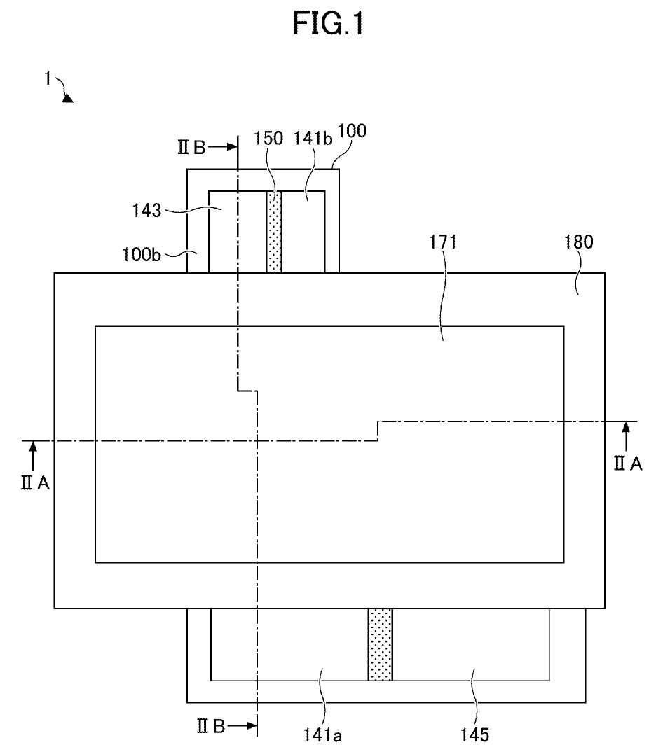

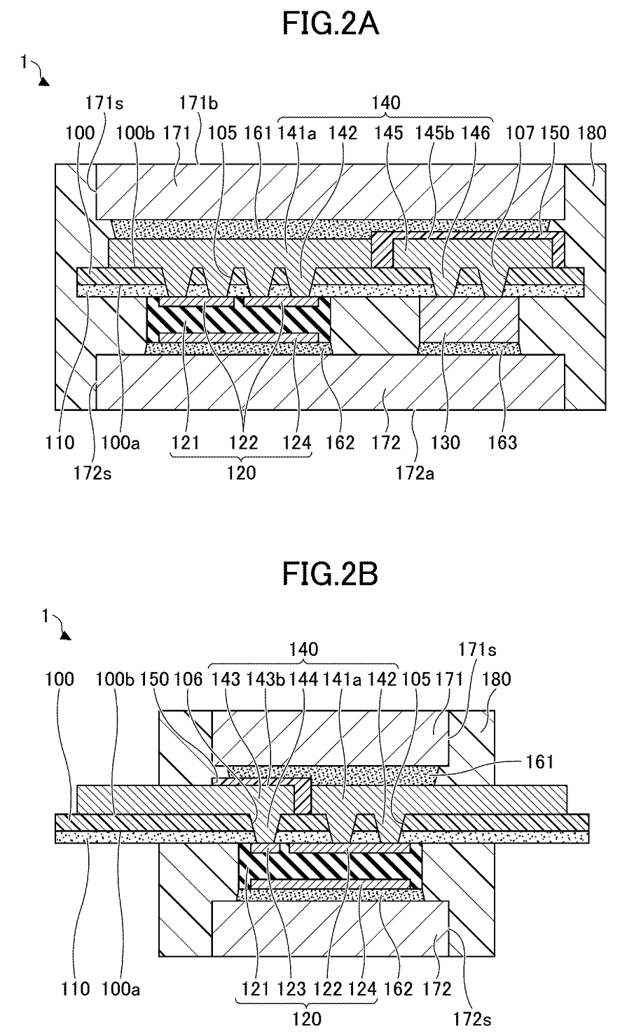

A semiconductor device configuration according to an embodiment is described. FIG. 1 is a plan view of a semiconductor device according to the embodiment. FIG. 2A is a sectional view of the semiconductor device of FIG. 1, taken along the line IIA-IIA. FIG. 2B is a sectional view of the semiconductor device of FIG. 1, taken along the line IIB-IIB.

As illustrated in FIGS. 1, 2A and 2B, a semiconductor device 1 according to the embodiment includes an insulating substrate 100, a bonding layer 110, a semiconductor element 120, a conductive member 130, a wiring layer 140, an insulating layer 150, a first wiring member 171, a second wiring member 172, and an encapsulation resin 180. The semiconductor device 1 may include multiple semiconductor elements 120. In FIG. 1, for convenience, part of the insulating layer 150 exposed from the encapsulation resin 180 is indicated by a dot pattern. In other drawings, the insulating layer 150 may be indicated by a dot pattern.

In this embodiment, for convenience, the first wiring member 171 side and the second wiring member 172 side of the semiconductor device 1 are referred to as “upper side” and “lower side”, respectively. Furthermore, a first surface and a second surface of each part or element of the semiconductor device 1 on the first wiring member 171 side and the second wiring member 172 side, respectively, are referred to as “upper surface” and “lower surface”, respectively. The semiconductor device 1, however, may be used in an inverted position and may be oriented at any angle. Furthermore, a plan view refers to a view of an object taken in a direction normal to an upper surface 100b of the insulating substrate 100 and a planar shape refers to the shape of an object as viewed in a direction normal to the upper surface 100b of the insulating substrate 100.

The insulating substrate 100 includes a lower surface 100a and the upper surface 100b, which is on the opposite side from the lower surface 100a in the thickness direction of the insulating substrate 100. For example, a resin film or the like may be used as the insulating substrate 100. Examples of materials for the resin film include insulating resins such as polyimide resins, polyethylene resins, and epoxy resins. The insulating substrate 100 may have flexibility, for example. Here, flexibility refers to a property that allows bending and deflection. The insulating substrate 100 may have any shape and size as desired. The planar shape of the insulating substrate 100 is, for example, a rectangular shape. The thickness of the insulating substrate 100 is, for example, approximately 50 μm to approximately 100 μm.

The bonding layer 110 is stacked on the lower surface 100a of the insulating substrate 100. The bonding layer 110 may be placed on the entirety of the lower surface 100a of the insulating substrate 100. The bonding layer 110 may alternatively be placed on only part of the lower surface 100aof the insulating substrate 100 on an as-needed basis. Examples of materials for the bonding layer 110 include epoxy, polyimide, and silicone adhesives. The thickness of the bonding layer 110 is, for example, approximately 20 μm to approximately 40 μm.

The semiconductor element 120 is a device that uses, for example, silicon (Si) or silicon carbide (SiC). A device that uses, for example, gallium nitride (GaN) or gallium arsenide (GaAs) may also be used as the semiconductor element 120. Examples of the semiconductor element 120 include semiconductor devices serving as active devices (for example, silicon chips such as a CPU), insulated gate bipolar transistors (IGBTs), metal-oxide-semiconductor field-effect transistors (MOSFETs), and diodes. The semiconductor element 120 according to this embodiment is provided with electrodes on its top side and bottom side. The semiconductor element 120 may have any shape and size as desired. The planar shape of the semiconductor element 120 is, for example, a rectangular shape. The thickness of the semiconductor element 120 is, for example, approximately 50 μm to approximately 500 μm.

The semiconductor element 120 includes a body 121, a first electrode 122 and a second electrode 123 positioned on one side (upper side) of the body 121 in its thickness direction, and a third electrode 124 positioned on the opposite side of the body 121 from the first electrode 122 and the second electrode 123 in the thickness direction. The semiconductor element 120 is bonded to the lower surface 100a of the insulating substrate 100 through the bonding layer 110 with the first electrode 122 and the second electrode 123 facing toward the insulating substrate 100. The first electrode 122, the second electrode 123, and the third electrode 124 may serve as a source electrode, a gate electrode, and a drain electrode, respectively, for example.

Examples of materials for the first electrode 122, the second electrode 123, and the third electrode 124 include metals such as aluminum (Al) and copper (Cu) and alloys including at least one type of metal selected from these metals. A surface treatment layer may be formed on an electrode surface on an as-needed basis. Examples of surface treatment layers include a gold (Au) layer, a Ni/Au layer (a laminated metal layer of a nickel (Ni) layer and a Au layer stacked in this order), and a Ni/Pd/Au layer (a laminated metal layer of a Ni layer, a palladium (Pd) layer, and a Au layer stacked in this order). For example, metal layers formed by electroless plating (electroless plating metal layers) may be used as these Au, Ni, and Pd layers. Furthermore, the Au layer is a metal layer of Au or a Au alloy, the Ni layer is a metal layer of Ni or a Ni alloy, and the Pd layer is a metal layer of Pd or a Pd alloy. In the following, the first electrode 122, the second electrode 123, and the third electrode 124 may be collectively referred to as “electrodes.”

The conductive member 130 is bonded to the lower surface 100a of the insulating substrate 100 through the bonding layer 110. The conductive member 130 may be formed of, for example, electrically conductive metal such as copper or a copper alloy. The conductive member 130 may have any shape and size as desired. The planar shape of the conductive member 130 is, for example, a rectangular shape. The thickness of the conductive member 130 is equal to the thickness of the semiconductor element 120 and may be, for example, approximately 50 μm to approximately 500 μm. According to this embodiment, objects may be equal in thickness if the difference between the thicknesses of the objects is less than or equal to 10 μm.

The wiring layer 140 includes first interconnects 141a and 141b, a first via interconnect 142 formed as a one-piece structure with each of the first interconnects 141a and 141b, a second interconnect 143, a second via interconnect 144 formed as a one-piece structure with the second interconnect 143, a third interconnect 145, and a third via interconnect 146 formed as a one-piece structure with the third interconnect 145. The first interconnects 141a and 141b, the second interconnect 143, and the third interconnect 145 are disposed on the upper surface 100b of the insulating substrate 100. The respective thicknesses of the first interconnects 141a and 141b, the second interconnect 143, and the third interconnect 145 may be, for example, approximately 50 μm to approximately 150 μm.

The first via interconnect 142 is placed in a through hole 105, which pierces through the insulating substrate 100 and the bonding layer 110 to expose the upper surface of the first electrode 122 of the semiconductor element 120. The second via interconnect 144 is placed in a through hole 106, which pierces through the insulating substrate 100 and the bonding layer 110 to expose the upper surface of the second electrode 123 of the semiconductor element 120. The third via interconnect 146 is placed in a through hole 107, which pierces through the insulating substrate 100 and the bonding layer 110 to expose the upper surface of the conductive member 130. According to the illustrated example, two or more through holes 105 and two or more through holes 107 are provided. Each of the number of through holes 105, the number of through holes 106, and the number of through holes 107 may be any number more than or equal to one.

Each of the first interconnects 141a and 141b is electrically connected to the first electrode 122 of the semiconductor element 120 via the first via interconnect 142. The second interconnect 143 is electrically connected to the second electrode 123 of the semiconductor element 120 via the second via interconnect 144. The third interconnect 145 is electrically connected to the conductive member 130 via the third via interconnect 146. The first interconnects 141a and 141b are at the same potential and may be therefore connected on the insulating substrate 100. In this case, the through hole 106 may be either provided or not provided.

The wiring layer 140 may have a structure where a metal layer is stacked on a seed layer, for example. In this case, a metal film formed by sputtering (a sputtered film) may be used as a seed layer, for example. Examples of seed layers formed by sputtering include a two-layer metal film in which a titanium (Ti) layer and a copper layer are stacked in this order. In this case, the thickness of the titanium layer may be, for example, approximately 10 nm to approximately 300 nm and the thickness of the copper layer may be, for example, approximately 100 nm to approximately 1000 nm. The titanium layer serves as an adhesion layer that improves the adhesion between the seed layer and the insulating substrate 100, the electrodes, etc. Furthermore, the titanium layer serves as a metal barrier layer that prevents copper of the copper layer, etc., from diffusing into the insulating substrate 100. Examples of materials for such metal films serving as an adhesion layer and a metal barrier layer include, in addition to titanium, titanium nitride (TiN), tantalum nitride (TaN), tantalum (Ta), and chromium (Cr). Example of materials for metal layers include copper and copper alloys. For example, a metal layer formed by electroplating (an electroplating metal layer) may be used as the metal layer.

The insulating layer 150 is placed at least between the first interconnects 141a and 141b and the second interconnect 143 on the upper surface 100b of the insulating substrate 100. The insulating layer 150 may also be placed between the first interconnects 141a and 141b and the third interconnect 145 on the upper surface 100b of the insulating substrate 100. The insulating layer 150 may also extend onto at least one of the upper surface of the first interconnect 141a, the upper surface of the first interconnect 141b, an upper surface 143b of the second interconnect 143, or an upper surface 145b of the third interconnect 145 from between the first interconnects 141a and 141b and the second interconnect 143.

The first wiring member 171 is placed on the upper side of (over) the first interconnects 141a and 141b and the second interconnect 143. The first wiring member 171 may also be placed over the third interconnect 145. The first wiring member 171 is joined to the first interconnect 141a and the insulating layer 150 extending onto the upper surface 143b of the second interconnect 143 via a first electrically conductive bonding layer 161. Preferably, the first wiring member 171 is further joined to the insulating layer 150 extending onto the upper surface 145b of the third interconnect 145 via the first electrically conductive bonding layer 161.

The second wiring member 172 is placed on the lower side of (under) the semiconductor element 120. Preferably, the second wiring member 172 is further placed on the lower side of (under) the conductive member 130. According to the illustrated example, the second wiring member 172 is electrically connected to the third electrode 124 of the semiconductor element 120 via a second electrically conductive bonding layer 162. Furthermore, the conductive member 130 is placed on the second wiring member 172 through a third electrically conductive bonding layer 163. The conductive member 130 is electrically connected to the third interconnect 145 via the third via interconnect 146. That is, the third electrode 124 is electrically connected to the third interconnect 145 via the second electrically conductive bonding layer 162, the second wiring member 172, the third electrically conductive bonding layer 163, the conductive member 130, and the third via interconnect 146.

The first wiring member 171 and the second wiring member 172 may be formed of, for example, copper, a copper alloy, or the like. Each of the first wiring member 171 and the second wiring member 172 may also be a constituent member of a wiring substrate such as a ceramic substrate. The first wiring member 171 and the second wiring member 172 may serve as heat dissipating components that release heat resulting from the operation of the semiconductor element 120 to the outside.

The encapsulation resin 180 covers the insulating substrate 100, the bonding layer 110, the semiconductor element 120, the conductive member 130, the first interconnects 141a and 141b, the second interconnect 143, and the third interconnect 145. The encapsulation resin 180 may be so provided as to cover a side surface 171s of the first wiring member 171 and a side surface 172s of the second wiring member 172 and expose an upper surface 171b of the first wiring member 171 and a lower surface 172a of the second wiring member 172. One or both of the upper surface 171b of the first wiring member 171 and the lower surface 172a of the second wiring member 172 may be joined to a water-based cooler or the like.

Part of the insulating substrate 100, part of the bonding layer 110, part of the first interconnects 141a and 141b, part of the second interconnect 143, and part of the third interconnect 145 protrude from the encapsulation resin 180 in a plan view. The parts of the first interconnects 141a and 141b, the second interconnect 143, and the third interconnect 145 protruding from the encapsulation resin 180 may be used as external connection terminals. As the encapsulation resin 180, for example, insulating resin such as thermosetting epoxy resin that contains filler may be used.

Part of the insulating layer 150 is exposed from the encapsulation resin 180 and is positioned between the parts of the first interconnect 141b and the second interconnect 143 protruding from the encapsulation resin 180. Furthermore, another part of the insulating layer 150 is exposed from the encapsulation resin 180 and is positioned between the parts of the first interconnect 141a and the third interconnect 145 protruding from the encapsulation resin 180. This makes it possible to increase the insulation between adjacent interconnects.

For example, in a plan view, the second interconnect 143 protrudes from a first side of the encapsulation resin 180 and the third interconnect 145 protrudes from a second side of the encapsulation resin 180. The first side and the second side are opposite from each other across the encapsulation resin 180 in a plan view. Furthermore, in a plan view, the first interconnects 141a and 141b protrude from both sides (namely, opposite sides) of the encapsulation resin 180. That is, for example, the first interconnect 141a and the first interconnect 141b protrude from the second side and the first side, respectively, of the encapsulation resin 180. In this case, for example, in a plan view, the first interconnect 141b protruding from the first side of the encapsulation resin 180 is adjacent to the second interconnect 143 across the insulating layer 150, and the first interconnect 141a protruding from the second side of the encapsulation resin 180 is adjacent to the third interconnect 145 across the insulating layer 150.

The first interconnects 141a and 141b protrude from the encapsulation resin 180 in opposite directions from each other. Therefore, the first interconnect 141b protruding from the first side of the encapsulation resin 180 may be used to provide a reference potential for a signal passing through the second interconnect 143 (for example, a gate signal). Furthermore, the first interconnect 141a protruding from the second side of the encapsulation resin 180 may be used as a negative terminal (for example, a source terminal). In addition, the third interconnect 145 adjacent to the first interconnect 141a may be used as a positive terminal (for example, a drain terminal).

Thus, according to the semiconductor device 1, the first interconnects 141a and 141b, the second interconnect 143, and the third interconnect 145 disposed on the upper surface 100b of the insulating substrate 100 protrude outside directly from the encapsulation resin 180 without using bonding wires to serve as external connection terminals. Therefore, there is no need to provide a spacer for ensuring a space for placing bonding wires in the encapsulation resin 180, so that the thickness of the semiconductor device 1 can be reduced.

Furthermore, according to semiconductor devices that require a spacer for ensuring a space for placing bonding wires, the spacer as well serves as a path that electrically connects a semiconductor device and external connection terminals, and inductance is therefore likely to increase. In contrast, according to the semiconductor device 1, no spacer is necessary. Therefore, it is possible to reduce the length of a path that electrically connects a semiconductor device and external connection terminals, so that it is possible to reduce inductance.

Furthermore, according to the semiconductor device 1, there is no need for a spacer. Therefore, it is possible to reduce the number of components and assembly cost. Furthermore, because no spacer is necessary, it is possible to reduce the number of electrically conductive bonding layers to only two in the semiconductor device 1. Therefore, it is possible to increase connection reliability.

In addition, according to the semiconductor device 1, the insulating layer 150 is interposed between adjacent interconnects. Therefore, it is possible to increase the connection reliability between adjacent interconnects.

Moreover, because the insulating layer 150 extends onto the upper surface 143b of the second interconnect 143, it is possible to place the first electrically conductive bonding layer 161 on the insulating layer 150 extending onto the upper surface 143b of the second interconnect 143. This increases the area of contact between the first wiring member 171 serving as a heat dissipating component and the first electrically conductive bonding layer 161. Therefore, heat resulting from the operation of the semiconductor element 120 is likely to be released to the first wiring member 171, it is possible to increase the heat dissipation of the semiconductor device 1. In the case where the side surface 171s of the first wiring member 171 is covered with the encapsulation resin 180, there is a limit to increasing the size of the first wiring member 171. Therefore, increasing the area of contact between the first wiring member 171 and the first electrically conductive bonding layer 161 is effective in increasing heat dissipation.

Furthermore, because the insulating layer 150 extends onto the upper surface 145b of the third interconnect 145, it is also possible to place the first electrically conductive bonding layer 161 on the insulating layer 150 extending onto the upper surface 145b of the third interconnect 145. This further increases the area of contact between the first wiring member 171 and the first electrically conductive bonding layer 161. Therefore, heat resulting from the operation of the semiconductor element 120 is more likely to be released to the first wiring member 171, it is possible to further increase the heat dissipation of the semiconductor device 1.

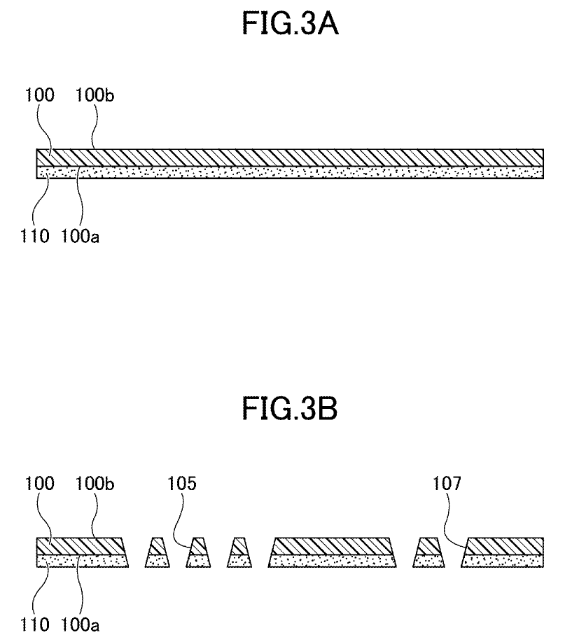

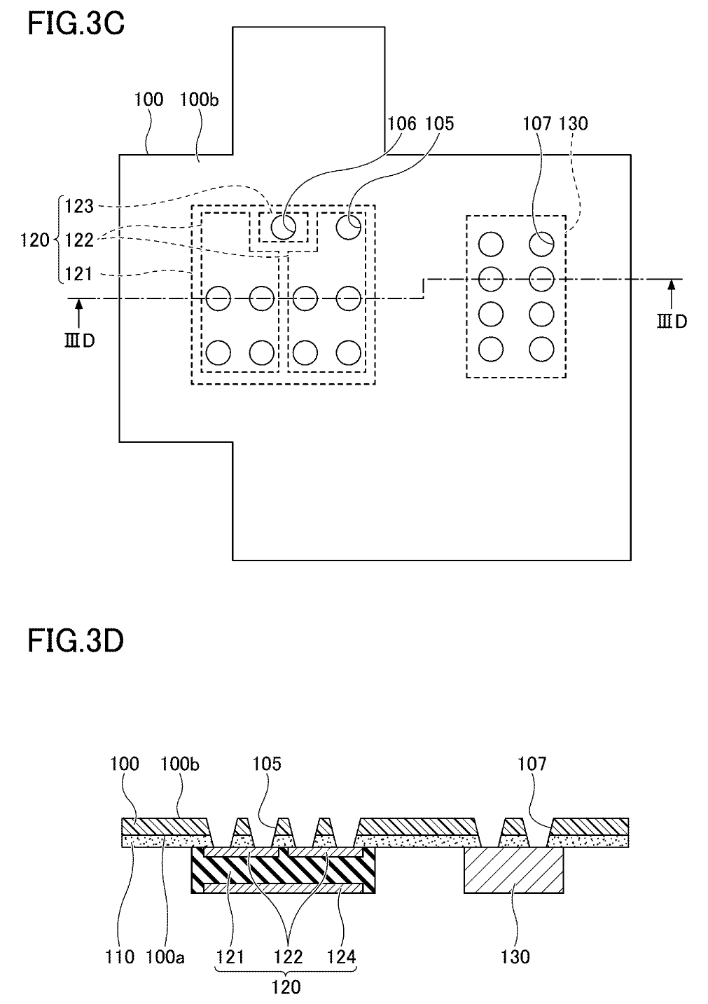

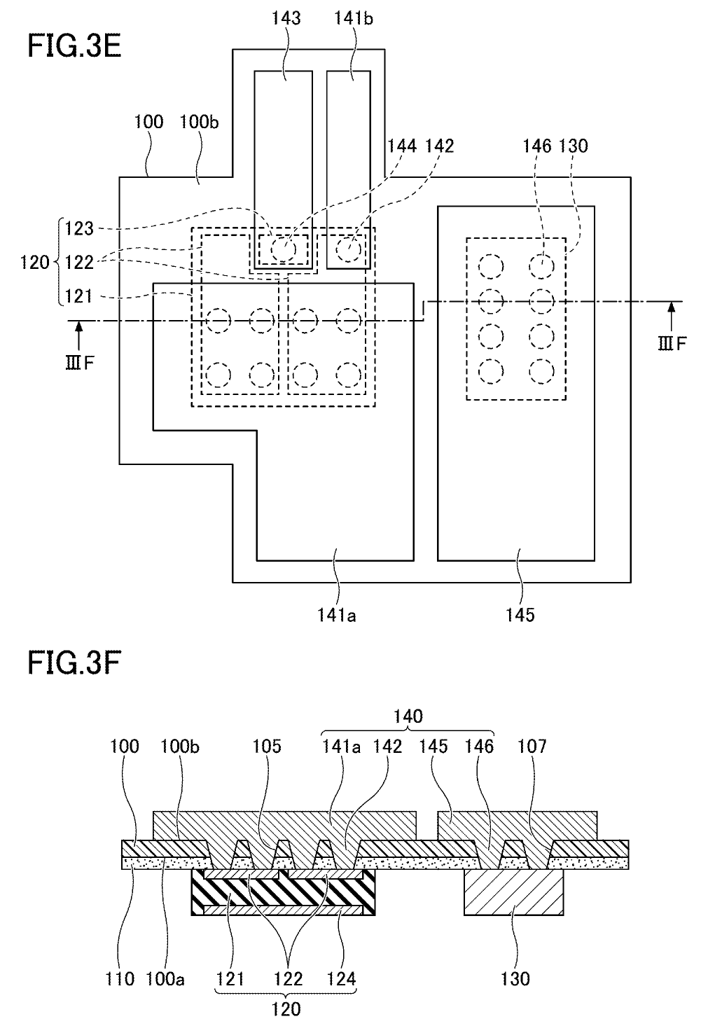

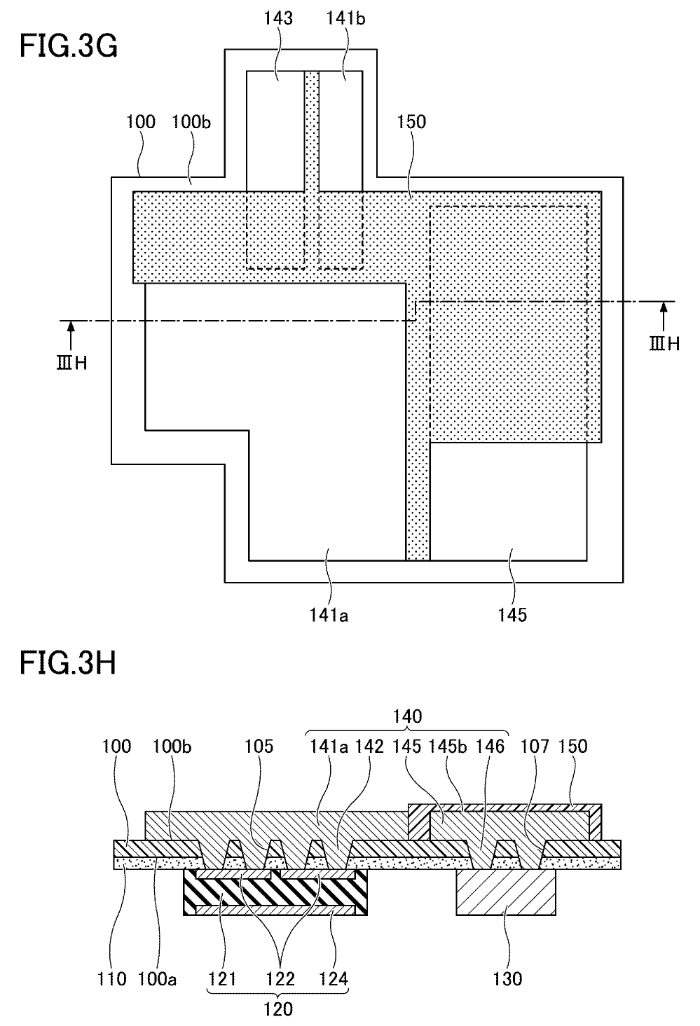

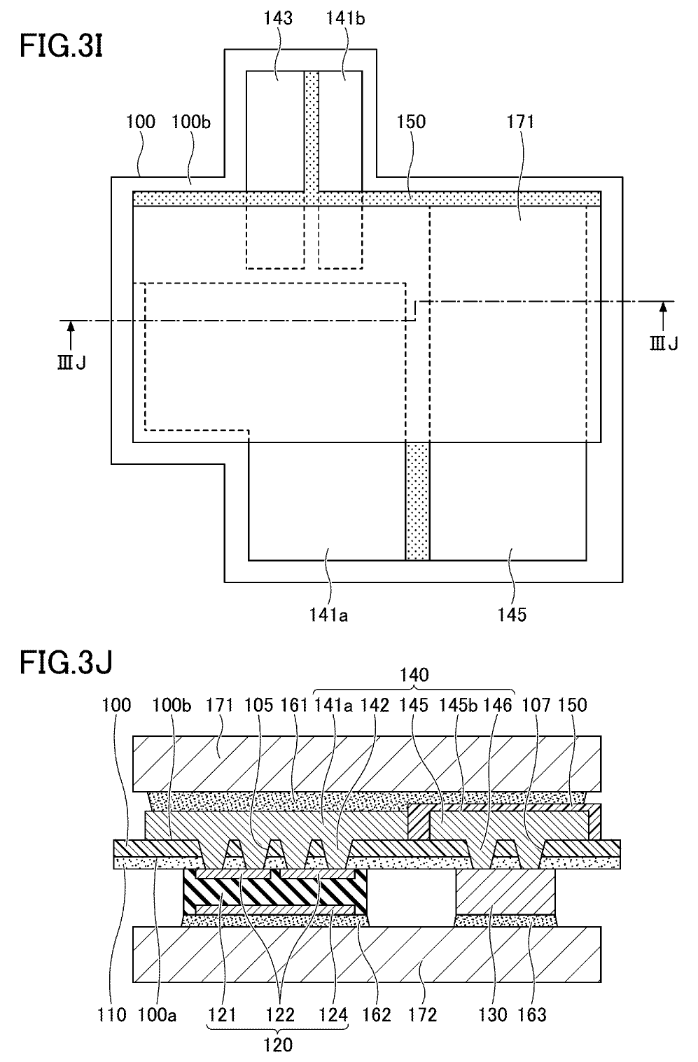

Next, a method of manufacturing a semiconductor device according to the embodiment is described. FIGS. 3A through 3J are diagrams illustrating a process for manufacturing a semiconductor device according to the embodiment. In the following description, the case of manufacturing a single semiconductor device is illustrated, but a so-called multi-piece manufacturing method, namely, manufacturing parts each to become the semiconductor device 1 all together and thereafter separating the parts into individual pieces to manufacture multiple semiconductor devices 1, may also be employed. For convenience of description, parts to ultimately become constituent elements of the semiconductor device 1 are referred to using the reference numerals of the final constituent elements.

First. as illustrated in FIG. 3A, the insulating substrate 100 having the lower surface 100a and the upper surface 100b and the bonding layer 110 are prepared. The bonding layer 110 is provided on the lower surface 100a of the insulating substrate 100 in such a manner as to cover the entirety of the lower surface 100a.

Next, as illustrated in FIG. 3B, the through holes 105 through 107 piercing through the insulating substrate 100 and the bonding layer 110 in their thickness direction are formed where necessary in the insulating substrate 100 and the bonding layer 110. The position of the through hole 106 is as illustrated in FIG. 2B. The through holes 105 through 107 may be formed by, for example, punching or laser processing using a CO₂ laser, a UV-YAG laser or the like. The through hole 105 is formed at a position where the first electrode 122 of the semiconductor element 120 is to be exposed in the subsequent process. The through hole 106 is formed at a position where the second electrode 123 of the semiconductor element 120 is to be exposed in the subsequent process. The through hole 107 is formed at a position where the upper surface of the conductive member 130 is to be exposed in the subsequent process. Each of the number of through holes 105, the number of through holes 106, and the number of through holes 107 may be any number more than or equal to one.

Next, as illustrated in FIGS. 3C and 3D, the semiconductor element 120 and the conductive member 130 are bonded to the insulating substrate 100 by the bonding layer 110. At this point, with the first electrode 122 and the second electrode 123 of the semiconductor element 120 facing the lower surface 100a of the insulating substrate 100, alignment is performed such that the through hole 105 lies on top of the first electrode 122 and the through hole 106 lies on top of the second electrode 123 in a plan view. Furthermore, alignment is performed such that the through hole 107 lies on top of the upper surface of the conductive member 130 in a plan view. FIG. 3C is a plan view and FIG. 3D is a sectional view taken along the line IIID-IIID of FIG. 3C.

Next, as illustrated in FIGS. 3E and 3F, the wiring layer 140 is formed. The wiring layer 140 includes the first interconnects 141a and 141b, the first via interconnect 142 formed as a one-piece structure with each of the first interconnects 141a and 141b, the second interconnect 143, the second via interconnect 144 formed as a one-piece structure with the second interconnect 143, the third interconnect 145, and the third via interconnect 146 formed as a one-piece structure with the third interconnect 145. The first interconnects 141a and 141b, the second interconnect 143, and the third interconnect 145 are disposed on the upper surface 100b of the insulating substrate 100. The first via interconnect 142 is placed in the through hole 105, which pierces through the insulating substrate 100 and the bonding layer 110 to expose the upper surface of the first electrode 122 of the semiconductor element 120. The second via interconnect 144 is placed in the through hole 106, which pierces through the insulating substrate 100 and the bonding layer 110 to expose the upper surface of the second electrode 123 of the semiconductor element 120. The third via interconnect 146 is placed in the through hole 107, which pierces through the insulating substrate 100 and the bonding layer 110 to expose the upper surface of the conductive member 130.

The wiring layer 140 may be formed using, for example, the semi-additive process. Specifically, a seed layer is so formed as to cover the entirety of the upper surface 100b of the insulating substrate 100 and the entirety of the inner surface of each of the through holes 105 through 107. The seed layer may be formed by, for example, sputtering or electroless plating. For example, in the case of forming the seed layer by sputtering, first, a Ti layer is so formed by depositing titanium by sputtering as to cover the upper surface 100b of the insulating substrate 100 and the inner surfaces of the through holes 105 through 107. Thereafter, a Cu layer is formed by depositing copper by sputtering on the Ti layer. As a result, a seed layer having a two-layer structure (Ti layer/Cu layer) can be formed. In the case of forming the seed layer by electroless plating, for example, a seed layer composed of a Cu layer (a single-layer structure) can be formed by electroless plating.

Next, a plating resist layer in which openings are formed where the wiring layer 140 is to be formed, namely, where the first interconnects 141a and 141b, the second interconnect 143, and the third interconnect 145 are to be formed, is formed on the seed layer. Next, by electroplating using the seed layer as a plating current path, a metal layer of copper or the like is formed in the openings of the plating resist layer. Thereafter, the plating resist layer is removed. Next, using the metal layer as a mask, the seed layer is removed by wet etching. In this manner, the wiring layer 140 including the seed layer and the metal layer can be formed. For example, the insulating substrate 100, the bonding layer 110, and the wiring layer 140 constitute a flexible printed circuit. FIG. 3E is a plan view and FIG. 3F is a sectional view taken along the line IIIF-IIIF of FIG. 3E.

Next, in the process illustrated in FIGS. 3G and 3H, the insulating layer 150 is formed on the upper surface 100b of the insulating substrate 100. The insulating layer 150 may be formed by, for example, applying epoxy resin or the like in liquid or paste form by potting or the like through a mask that opens predetermined positions and thereafter curing the applied epoxy resin or the like by heating or exposure to UV radiation. The insulating layer 150 may also be formed by applying photosensitive epoxy resin or the like in liquid or paste form over the entirety of the upper surface 100b of the insulating substrate 100 and patterning the applied photosensitive epoxy resin or the like into a predetermined shape by exposure to light and development. Alternatively, in place of epoxy resin or the like in liquid or paste form, a film of epoxy resin or the like may be applied as a laminate.

Here, by way of example, the insulating layer 150 is formed between the first interconnects 141a and 141b and the second interconnect 143 and between the first interconnects 141a and 141b and the third interconnect 145. The insulating layer 150 is further formed to extend onto the upper surface of the first interconnect 141a, the upper surface of the first interconnect 141b, the upper surface 143b of the second interconnect 143, and the upper surface 145b of the third interconnect 145. FIG. 3G is a plan view and FIG. 3H is a sectional view taken along the line IIIH-IIIH of FIG. 3G.

Next, in the process illustrated in FIGS. 3I and 3J, the first wiring member 171 is placed over the wiring layer 140 and the insulating layer 150 through the first electrically conductive bonding layer 161. Furthermore, the second wiring member 172 is placed below the semiconductor element 120 and the conductive member 130 through the second electrically conductive bonding layer 162 and the third electrically conductive bonding layer 163, respectively. Here, by way of example, the first wiring member 171 is joined to the insulating layer 150 extending onto the upper surface 143b of the second interconnect 143, the insulating layer 150 extending onto the upper surface 145b of the third interconnect 145, and the first interconnect 141a via the first electrically conductive bonding layer 161. Furthermore, the second wiring member 172 is joined to the third electrode 124 of the semiconductor element 120 via the second electrically conductive bonding layer 162 and to the conductive member 130 via the third electrically conductive bonding layer 163. The first electrically conductive bonding layer 161, the second electrically conductive bonding layer 162, and the third electrically conductive bonding layer 163 may be, for example, solder layers or sintered metal layers containing silver, copper, or the like. The first electrically conductive bonding layer 161, the second electrically conductive bonding layer 162, and the third electrically conductive bonding layer 163 may also be formed of conductive paste such as silver paste. The first wiring member 171 and the second wiring member 172 may be joined simultaneously or joined sequentially using electrically conductive bonding layers having different melting points. In the case of using electrically conductive bonding layers having different melting points, for example, solder may be used for the first electrically conductive bonding layer 161 and sintered metal (for example, silver) may be used for the second electrically conductive bonding layer 162 and the third electrically conductive bonding layer 163. In this case, after joining the second wiring member 172 via the second electrically conductive bonding layer 162 and the third electrically conductive bonding layer 163 having a higher melting point, the first wiring member 171 may be joined via the first electrically conductive bonding layer 161. FIG. 3I is a plan view and FIG. 3J is a sectional view taken along the line IIIJ-IIIJ of FIG. 3I.

Next, by forming the encapsulation resin 180, the semiconductor device 1 illustrated in FIGS. 1, 2A and 2B is completed. The encapsulation resin 180 is, for example, so formed as to cover the insulating substrate 100, the bonding layer 110, the semiconductor element 120, the conductive member 130, the first interconnects 141a and 141b, the second interconnect 143, and the third interconnect 145. The encapsulation resin 180 may be so formed as to cover the side surface 171sof the first wiring member 171 and the side surface 172s of the second wiring member 172 and expose the upper surface 171b of the first wiring member 171 and the lower surface 172a of the second wiring member 172.

Part of the insulating substrate 100, part of the bonding layer 110, part of the first interconnects 141a and 141b, part of the second interconnect 143, and part of the third interconnect 145 protrude from the encapsulation resin 180. For example, insulating resin such as thermosetting epoxy resin containing filler may be used as the encapsulation resin 180. The encapsulation resin 180 may be formed by, for example, transfer molding using an encapsulation mold.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority or inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
an insulating substrate;
a semiconductor element including a first electrode and a second electrode, the semiconductor element being bonded to a first surface of the insulating substrate through a bonding layer with the first electrode and the second electrode facing toward the insulating substrate;
a first interconnect on a second surface of the insulating substrate on an opposite side from the first surface, the first interconnect being electrically connected to the first electrode via a first via interconnect piercing through the insulating substrate and the bonding layer;
a second interconnect on the second surface of the insulating substrate, the second interconnect being electrically connected to the second electrode via a second via interconnect piercing through the insulating substrate and the bonding layer;
an insulating layer positioned between the first interconnect and the second interconnect on the second surface of the insulating substrate;
a first wiring member over the first interconnect and the second interconnect;
a second wiring member below the semiconductor element; and
an encapsulation resin covering the semiconductor element, the first interconnect, and the second interconnect,
wherein a part of the first interconnect and a part of the second interconnect protrude from the encapsulation resin in a plan view.

2. The semiconductor device as claimed in claim 1, wherein
the insulating layer extends, from between the first interconnect and the second interconnect, onto a surface of the second interconnect on an opposite side from the insulating substrate, and
the first wiring member is joined, via a first electrically conductive bonding layer, to the first interconnect and the insulating layer extending onto the surface of the second interconnect.

3. The semiconductor device as claimed in claim 2, wherein a part of the insulating layer is exposed from the encapsulation resin to be positioned between the part of the first interconnect protruding from the encapsulation resin and the part of the second interconnect protruding from the encapsulation resin.

4. The semiconductor device as claimed in claim 2, wherein the encapsulation resin covers a side surface of the first wiring member and a side surface of the second wiring member and exposes a surface of the first wiring member on an opposite side from the first interconnect and the second interconnect and a surface of the second wiring member on an opposite side from the semiconductor element.

5. The semiconductor device as claimed in claim 2, wherein
the semiconductor element further includes a third electrode on an opposite side from the first electrode and the second electrode, and
the second wiring member is electrically connected to the third electrode via a second electrically conductive bonding layer.

6. The semiconductor device as claimed in claim 5, further comprising:
a conductive member placed on the second wiring member through a third electrically conductive bonding layer; and
a third interconnect on the second surface of the insulating substrate, the third interconnect being electrically connected to the conductive member via a third via interconnect piercing through the insulating substrate and the bonding layer,
wherein a part of the third interconnect protrudes from the encapsulation resin in the plan view.

7. The semiconductor device as claimed in claim 6, wherein the insulating layer is further positioned between the first interconnect and the third interconnect.

8. The semiconductor device as claimed in claim 7, wherein
the insulating layer extends, from between the first interconnect and the third interconnect, onto a surface of the third interconnect on an opposite side from the insulating substrate, and
the first wiring member is joined, via the first electrically conductive bonding layer, to the insulating layer extending onto the surface of the third interconnect.

9. The semiconductor device as claimed in claim 7, wherein a part of the insulating layer is exposed from the encapsulation resin to be positioned between the part of the first interconnect protruding from the encapsulation resin and the part of the third interconnect protruding from the encapsulation resin.

10. The semiconductor device as claimed in claim 7, wherein
the part of the second interconnect protrudes from a first side of the encapsulation resin and the part of the third interconnect protrudes from a second side of the encapsulation resin in the plan view, the second side being opposite from the first side,
the part of the first interconnect protruding from the encapsulation resin includes a first part protruding from the first side of the encapsulation resin and a second part protruding from the second side of the encapsulation resin in the plan view, and
the first part of the first interconnect is adjacent to the part of the second interconnect across the insulating layer and the second part of the first interconnect is adjacent to the part of the third interconnect across the insulating layer in the plan view.

11. The semiconductor device as claimed in claim 1, wherein a part of the insulating substrate and a part of the bonding layer protrude from the encapsulation resin in the plan view.

12. The semiconductor device as claimed in claim 11, wherein the part of the first interconnect and the part of the second interconnect protruding from the encapsulation resin are on the part of the insulating substrate protruding from the encapsulation resin.

13. The semiconductor device as claimed in claim 1, wherein the part of the first interconnect and the part of the second interconnect protruding from the encapsulation resin form external connection terminals.
